(19) United States
(12) Patent Application Publication
(10) Pub. No.: US 2025/0324756 A1
(43) Pub. Date: Oct. 16, 2025

(54) DISPLAY DEVICE AND METHOD OF MANUFACTURING THE SAME

(71) Applicant: Samsung Display Co., Ltd., Yongin-si (KR)

(72) Inventors: Sun Kwun SON, Yongin-si (KR); Dong Hee SHIN, Yongin-si (KR)

(73) Assignee: Samsung Display Co., Ltd., Yongin-si (KR)

(21) Appl. No.: 18/983,564

(22) Filed: Dec. 17, 2024

(30) Foreign Application Priority Data
Apr. 15, 2024 (KR) 10-2024-0049884

(51) Int. Cl. H10D 86/40; H10D 86/01

(52) U.S. Cl. CPC H10D 86/421; H10D 86/021; H10D 86/481

(57) ABSTRACT

A display device includes a substrate, first and second active layers, and first and second electrode layers. The substrate includes a display area and a non-display area. The first active layer is disposed on the substrate. A portion of the first active layer forms a channel area of a driving transistor of the sub-pixel circuit. The first electrode layer is disposed on the first active layer. A portion of the first electrode layer forms a control electrode of the driving transistor. The second electrode layer includes a first portion overlapping the first electrode layer in a direction perpendicular to the substrate. The second active layer includes a first portion overlapping the first portion of the second electrode layer in the direction, and a second portion forming a channel area of a switching transistor of the sub-pixel circuit.

### CROSS-REFERENCE TO RELATED APPLICATION(S)

This U.S. non-provisional patent application claims priority to and the benefits of Korean Patent Application No. 10-2024-0049884, under 35 U.S.C. § 119, filed in the Korean Intellectual Property Office on Apr. 15, 2024, the entire contents of which are hereby incorporated by reference.

### BACKGROUND

### 1. Technical Field

The disclosure generally relates to a display device and a method of manufacturing the same.

### 2. Description of the Related Art

As information technology has developed, the importance of a display device, which is a connection medium between a user and information, has been highlighted. Accordingly, the use of display devices, such as liquid crystal display devices, organic light emitting display devices, and inorganic light emitting display devices, is increasing.

Research is being actively conducted on micro-light emitting diodes (LEDs) that may realize relatively high luminance and relatively faster response speed as compared to conventional LEDs. In a case of inorganic light emitting elements, such as micro-LEDs, it may be difficult to accurately implement a desired luminance as a center wavelength of a current may move according to a current density in association with using a pulse amplitude modulation (PAM) method. In a case of micro-LEDs, it may be possible to use a pulse width modulation (PWM) pixel driving method that expresses luminance by controlling the time in which current flows through the light emitting element.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

An aspect provides a display device capable of using a second active layer as a capacitor.

An aspect provides a method of manufacturing a display device, which is capable of using a second active layer as a capacitor.

Additional aspects will be set forth in the detailed description, which follows, and in part, will be apparent from the disclosure, or may be learned by practice of the disclosed embodiments and/or the claimed subject matter.

According to an aspect, a display device includes: a substrate, a first active layer, a first electrode layer, a second electrode layer, and a second active layer. The substrate includes a display area and a non-display area. The first active layer is disposed on the substrate. A portion of the first active layer forms a channel area of a driving transistor of a sub-pixel circuit. The first electrode layer is disposed on the first active layer. A portion of the first electrode layer forms a control electrode of the driving transistor. The second electrode layer includes a first portion overlapping the first electrode layer in a direction perpendicular to the substrate. The second active layer includes a first portion overlapping the first portion of the second electrode layer in the direction, and a second portion forming a channel area of a switching transistor of the sub-pixel circuit.

In an embodiment, the sub-pixel circuit may include a capacitor electrically connected to the control electrode of the driving transistor, and the capacitor may include electrodes formed by the portion of the first electrode layer, the first portion of the second electrode layer, and the first portion of the second active layer.

In an embodiment, the first portion of the second active layer may be a semiconductor pattern doped with impurities.

In an embodiment, the second electrode layer may further include a second portion, and in the direction, the second portion of the second electrode layer may be disposed between the second portion of the second active layer and the substrate.

In an embodiment, the display device may further include a third electrode layer disposed on the substrate. A portion of the third electrode layer may form a control electrode of the switching transistor. In a view in the direction, the third electrode layer may be spaced apart from the first portion of the second active layer.

In an embodiment, the display device may further include a light emitting element disposed on the display area and electrically connected to the sub-pixel circuit. The sub-pixel circuit may include a first sub-pixel circuit configured to control a light emitting time of the light emitting element, and a second sub-pixel circuit configured to provide a driving current to the light emitting element.

In an embodiment, the first sub-pixel circuit may include a first transistor, a first capacitor, a second transistor, a third transistor, a fourth transistor, a fifth transistor, and a sixth transistor. The first transistor may include a control electrode electrically connected to a first node, a first electrode electrically connected to a second node, and a second electrode electrically connected to a third node. The first capacitor may include a first electrode electrically connected to receive a sweep voltage and a second electrode electrically connected to the first node. The second transistor may include a control electrode electrically connected to receive a first write gate signal, a first electrode electrically connected to receive a data voltage, and a second electrode electrically connected to the second node. The third transistor may include a control electrode electrically connected to receive the first write gate signal, a first electrode electrically connected to the third node, and a second electrode electrically connected to the first node. The fourth transistor may include a control electrode electrically connected to receive an emission signal, a first electrode electrically connected to receive a (1-1)-th power voltage, and a second electrode electrically connected to the second node. The fifth transistor may include a control electrode electrically connected to receive the emission signal, a first electrode electrically connected to the third node, and a second electrode electrically connected to the second sub-pixel circuit. The sixth transistor may include a control electrode electrically connected to receive a first initialization gate signal, a first electrode electrically connected to receive a first initialization voltage, and a second electrode electrically connected to the first node.

In an embodiment, the first transistor may be an instance of the driving transistor, and each of the second transistor, the third transistor, and the sixth transistor may be a respective instance of the switching transistor.

In an embodiment, electrodes of the first capacitor may be formed by the portion of the first electrode layer, the first portion of the second electrode layer, and the first portion of the second active layer.

In an embodiment, the second sub-pixel circuit may include a seventh transistor, a second capacitor, an eighth transistor, a ninth transistor, a tenth transistor, an eleventh transistor, a twelfth transistor, and a thirteenth transistor. The seventh transistor may include a control electrode electrically connected to a fourth node electrically connected to the first sub-pixel circuit, a first electrode electrically connected to a fifth node, and a second electrode electrically connected to a sixth node. The second capacitor may include a first electrode electrically connected to receive a (1-2)-th power voltage and a second electrode electrically connected to the fourth node. The eighth transistor may include a control electrode electrically connected to receive a second write gate signal, a first electrode electrically connected to receive a data voltage, and a second electrode electrically connected to the fifth node. The ninth transistor may include a control electrode electrically connected to receive the second write gate signal, a first electrode electrically connected to the sixth node, and a second electrode electrically connected to the fourth node. The tenth transistor may include a control electrode electrically connected to receive an emission signal, a first electrode electrically connected to receive the (1-2)-th power voltage, and a second electrode electrically connected to the fifth node. The eleventh transistor may include a control electrode electrically connected to receive the emission signal, a first electrode electrically connected to the sixth node, and a second electrode electrically connected to the light emitting element. The twelfth transistor may include a control electrode electrically connected to receive a second initialization gate signal, a first electrode electrically connected to receive a first initialization voltage, and a second electrode electrically connected to the fourth node. The thirteenth transistor may include a control electrode electrically connected to receive a bias gate signal, a first electrode electrically connected to receive a second initialization voltage, and a second electrode electrically connected to the light emitting element.

In an embodiment, the seventh transistor may be an instance of the driving transistor, and each of the eighth transistor, the ninth transistor, and the twelfth transistor may be a respective instance of the switching transistor.

In an embodiment, electrodes of the second capacitor may be formed by the portion of first electrode layer, the first portion of the second electrode layer, and the first portion of the second active layer.

In an embodiment, the display device may further include a lower electrode layer disposed on the substrate. The lower electrode layer may be disposed between the first active layer and the substrate in the direction.

In an embodiment, at least a portion of the lower electrode layer may be electrically connected to the first portion of the second electrode layer.

In an embodiment, the at least the portion of the lower electrode layer and the first portion of the second electrode layer may be electrically connected to one another in a region overlapping the non-display area in the direction.

According to an aspect, a method of manufacturing a display device includes forming, on a substrate, a first active layer in a display area of the display device, a portion of the first active layer forming a channel area of a driving transistor of a sub-pixel circuit. The method further includes forming a first electrode layer on the first active layer, a portion of the first electrode layer forming a control electrode of the driving transistor. The method further includes forming, on the substrate, a second electrode layer including a first portion overlapping the first electrode layer in a direction perpendicular to the substrate. The method further includes forming, on the substrate, a second active layer. The second active layer includes a first portion overlapping the first portion of the second electrode layer in the direction, and a second portion forming a channel area of a switching transistor of the sub-pixel circuit.

In an embodiment, the sub-pixel circuit may include a capacitor electrically connected to the control electrode of the driving transistor, and the capacitor may include electrodes formed by the portion of the first electrode layer, the first portion of the second electrode layer, and the first portion of the second active layer.

In an embodiment, the first portion of the second active layer may be a semiconductor pattern doped with impurities.

In an embodiment, the method may further include forming a third electrode layer on the substrate, a portion of the third electrode forming a control electrode of the switching transistor. In a view in the direction, the third electrode layer may be spaced apart from the first portion of the second active layer.

In an embodiment, the method may further include forming a lower electrode layer on the substrate. At least a portion of the lower electrode layer may be electrically connected to the first portion of the second electrode layer.

According to various embodiments, a display device may secure greater capacitance by using a second active layer as a portion of a capacitor. The display device may be designed with a relatively high number of pixels per inch (PPI).

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 schematically illustrates a block diagram of a display device according to an embodiment.

FIG. 2 schematically illustrates a block diagram of a sub-pixel among sub-pixels of FIG. 1 according to an embodiment.

FIG. 3 schematically illustrates an equivalent circuit diagram of an example of the sub-pixel of FIG. 2 according to an embodiment.

FIG. 4 schematically illustrates a top plan view of a display panel of FIG. 1 according to an embodiment.

FIG. 5 schematically illustrates a cross-sectional view of a display panel of FIG. 4 according to an embodiment.

FIG. 6 schematically illustrates a cross-sectional view of a display panel of FIG. 4 according to an embodiment.

FIG. 7 schematically illustrates a cross-sectional view of a substrate and a pixel circuit layer of FIG. 5 according to an embodiment.

FIG. 8 schematically illustrates a layout view of an example of a pixel PXL of FIG. 1 according to an embodiment.

FIG. 9 schematically illustrates a layout view of a lower electrode layer of FIG. 8 according to an embodiment.

FIG. 10 schematically illustrates a layout view of a first active layer of FIG. 8 according to an embodiment.

FIG. 11 schematically illustrates a layout view of a first electrode layer of FIG. 8 according to an embodiment.

FIG. 12 schematically illustrates a layout view of a second electrode layer of FIG. 8 according to an embodiment.

FIG. 13 schematically illustrates a layout view of a second active layer of FIG. 8 according to an embodiment.

FIG. 14 schematically illustrates a layout view of a third electrode layer of FIG. 8 according to an embodiment.

FIG. 15 schematically illustrates a layout view of a first connection electrode layer, a first contact hole, and a second contact hole of FIG. 8 according to an embodiment.

FIG. 16 schematically illustrates a layout view of a first connection electrode layer, a second connection electrode layer, and a via hole of FIG. 8 according to an embodiment.

FIG. 17 schematically illustrates an example of a lower electrode layer of a display device according to an embodiment.

FIG. 18 schematically illustrates a flowchart of a method of manufacturing a display device according to an embodiment.

FIG. 19 schematically illustrates a block diagram of a display system according to an embodiment.

FIG. 20 to FIG. 23 schematically illustrate perspective views of application examples of the display system of FIG. 19 according to some embodiments.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the terms “substantially,” if used herein, and unless otherwise specified, may mean within 5% of a referenced value. For example, substantially perpendicular may mean within ±5% of being parallel. The terms “about” and “approximately,” if used herein, and unless otherwise specified, may mean within one or more standard deviations, or within ±30%, ±20%, ±10%, or ±5% of a stated value. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4. Furthermore, the expression “being the same” may mean “being substantially the same.” For instance, the expression “being the same” may include a range that can be tolerated by those skilled in the art. Other expressions may also be expressions from which “substantially” has been omitted.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

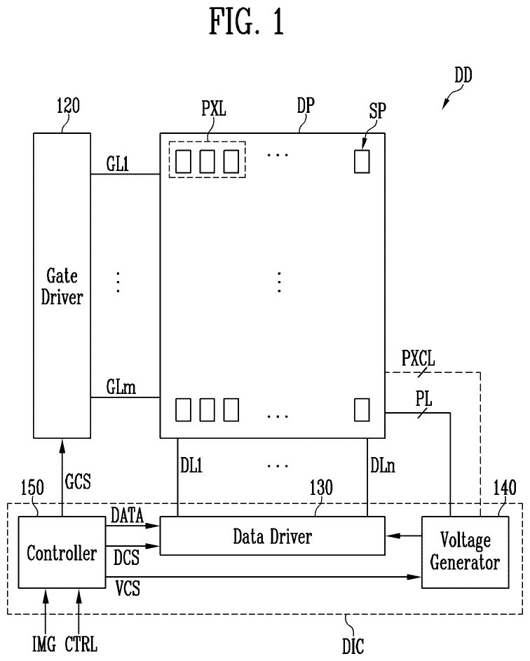

FIG. 1 schematically illustrates a block diagram of a display device according to an embodiment.

Referring to FIG. 1, a display device DD may include a display panel DP, a gate driver 120, a data driver 130, a voltage generator 140, and a controller 150.

The display panel DP includes sub-pixels SP. The sub-pixels SP may be electrically connected to the gate driver 120 through first to m-th gate lines GL1 to GLm, where “m” is a positive integer greater than one (1). The sub-pixels SP may be electrically connected to the data driver 130 through first to n-th data lines DL1 to DLn, where “n” is a positive integer greater than one (1) and may be equivalent to or different from “m.”

The sub-pixels SP may generate light of two or more colors. For example, the sub-pixels SP may respectively generate light of a color, such as red, green, blue, cyan, magenta, yellow, or the like.

Two or more of the sub-pixels SP may configure one (or a) pixel PXL. For example, the pixel PXL may include three sub-pixels as shown in FIG. 1. The pixel PXL may emit light of various colors and with various luminance depending on a combination of light emitted from the sub-pixels SP included as part of the pixel PXL.

The gate driver 120 may be electrically connected to the sub-pixels SP arranged in a row direction through the first to m-th gate lines GL1 to GLm. The row direction may be a horizontally extending direction. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and/or the like.

The gate driver 120 may be disposed on one (or a) side of the display panel DP. However, embodiments are not limited to this example arrangement. For example, the gate driver 120 may be divided into two or more physically and/or logically separated drivers, and the drivers may be disposed on one (or a) side of the display panel DP and the other (or another) side of the display panel DP opposite to the one side. As described above, the gate driver 120 may be disposed around (or partially around) the display panel DP in a view in a direction extending into or out of the page in various forms according to embodiments. Hereinafter, a view extending into or out of the page will be referred to as a plan view unless otherwise specified.

The data driver 130 may be electrically connected to the sub-pixels SP arranged in a column direction through the first to n-th data lines DL1 to DLn. The row direction may be a vertically extending direction, which may be transverse to and in a same plane as the horizontally extending direction. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and/or the like.

The data driver 130 may receive one or more voltages from the voltage generator 140. The data driver 130 may use the received voltages to apply data signals having grayscale voltages corresponding to the image data DATA to the first to n-th data lines DL1 to DLn. In response to a gate signal being applied to a gate line among the first to m-th gate lines GL1 to GLm, data signals corresponding to the image data DATA may be applied to a data line among the first to n-th data lines DL1 to DLn. The sub-pixels SP may generate light corresponding to the data signals, and the display panel DP may display an image.

In some embodiments, the gate driver 120 and the data driver 130 may include one or more complementary metal-oxide semiconductor (CMOS) circuit elements, but embodiments are not limited to this example.

The voltage generator 140 may operate in response to a voltage control signal VCS from the controller 150. The voltage generator 140 may be configured to generate one or more voltages. Hereinafter, it will be assumed that the voltage generator 140 is configured to generate multiple voltages. The voltage generator 140 may provide the generated voltages to components of the display device DD, such as the gate driver 120, the data driver 130, and the controller 150. The voltage generator 140 may generate the voltages by receiving an input voltage from outside of (or a source external to) the display device DD and regulating the received voltage. It, however, is contemplated that the input voltage may be received from any other suitable source.

The voltage generator 140 may generate a first power voltage and a second power voltage. The generated first and second power voltages may be provided to the sub-pixels SP through one or more power lines, such as power line PL. In some embodiments, at least one of the first and second power voltages may be provided from outside of the display device DD.

In some embodiments, the voltage generator 140 may provide various voltages and/or signals. For example, the voltage generator 140 may provide one or more initialization voltages applied to the sub-pixels SP. For example, during (or as part of) a sensing operation to sense electrical characteristics of transistors and/or light emitting elements of the sub-pixels SP, a determined (or selected) reference voltage may be applied to the first to n-th data lines DL1 to DLn, and the voltage generator 140 may generate the reference voltage and transmit the reference voltage to the data driver 130. For example, during (or as part of) a display operation for displaying an image via the display panel DP, common pixel control signals may be applied to the sub-pixels SP, and the voltage generator 140 may generate the common pixel control signals. In embodiments, the voltage generator 140 may provide common pixel control signals to the sub-pixels SP through one or more pixel control lines, such as pixel control line PXCL, which is illustrated in FIG. 1 using a dashed line. Hereinafter, it will be assumed that the display device DD includes multiple pixel control lines PXCL. Although FIG. 1 schematically illustrates the pixel control lines PXCL being electrically connected between the voltage generator 140 and the display panel DP, embodiments are not limited to this example structure. For example, the pixel control lines PXCL may be electrically connected between the gate driver 120 and the display panel DP. In a case in which the pixel control lines PXCL are electrically connected between the gate driver 120 and the display panel DP, the common pixel control signals may be transmitted from the voltage generator 140 to the pixel control lines PXCL through the gate driver 120.

The controller 150 may control various operations of the display device DD. The controller 150 may receive input image data IMG and a control signal CTRL corresponding to the input image data DATA from a source outside of (or external to) the display device DD, but any suitable source may be utilized. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row or in any other suitable arrangement.

Two or more components of the data driver 130, the voltage generator 140, and the controller 150 may be mounted on or combined as part of one (or an) integrated circuit. As shown in FIG. 1, the data driver 130, the voltage generator 140, and the controller 150 may be included in (or as part of) a driver integrated circuit DIC and this concept is schematically illustrated through the use of a dashed box around the data driver 130, the voltage generator 140, and the controller 150. In a case in which the data driver 130, the voltage generator 140, and the controller 150 are incorporated as part of a same driver integrated circuit DIC, the data driver 130, the voltage generator 140, and the controller 150 may be functionally and/or logically separate components in one (or a) driver integrated circuit DIC. In some embodiments, at least one of the data driver 130, the voltage generator 140, and the controller 150 may be provided as a component separate from the driver integrated circuit DIC.

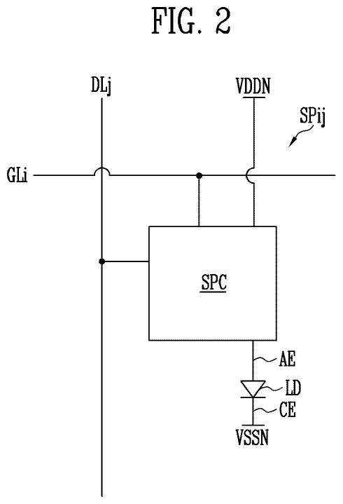

FIG. 2 schematically illustrates a block diagram of a sub-pixel among the sub-pixels of FIG. 1 according to an embodiment. In FIG. 2, among the sub-pixels SP of FIG. 1, a sub-pixel SPij disposed in an i-th row (where “i” is an integer greater than or equal to 1 and less than or equal to m) and a j-th column (where “j” is an integer greater than or equal to 1 and less than or equal to n) is schematically illustrated as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL in FIG. 1 to receive the first power voltage. The second power voltage node VSSN may be electrically connected to another one of the power lines PL in FIG. 1 to receive the second power voltage. The first power voltage may have a higher voltage level than the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may be configured to emit light according to a current flowing from the anode electrode AE to the cathode electrode CE.

The sub-pixel circuit SPC may be electrically connected to an i-th gate line GLi of the first to m-th gate lines GL1 to GLm of FIG. 1 and a j-th data line DLj of the first to n-th data lines DLI to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be electrically connected to at least one of the pixel control lines PXCL of FIG. 1. In a case in which the sub-pixel circuit SPC is electrically connected to at least one of the pixel control lines PXCL, the sub-pixel circuit SPC may control the light emitting element LD in further response to the pixel control signals received through the pixel control lines PXCL.

The sub-pixel circuit SPC may include circuit elements, for example one or more transistors and one or more capacitors. Hereinafter, it will be assumed that the sub-pixel circuit SPC includes multiple transistors and multiple capacitors.

The transistors of the sub-pixel circuit SPC may include P-type transistors and/or N-type transistors. In embodiments, the transistors of the sub-pixel circuit SPC may include a metal oxide silicon field effect transistor (MOSFET), but embodiments are not limited to this example type of transistor. In embodiments, the transistors of the sub-pixel circuit SPC may include at least one of an amorphous silicon semiconductor, a monocrystalline silicon semiconductor, a polycrystalline silicon semiconductor, and an oxide semiconductor.

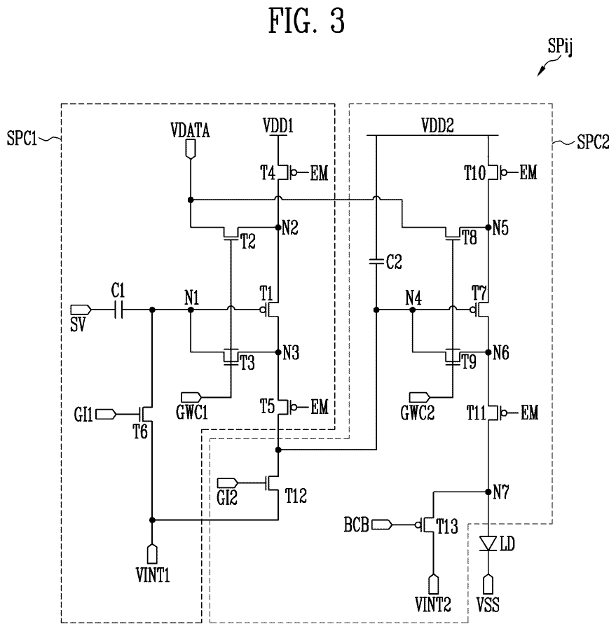

FIG. 3 schematically illustrates an equivalent circuit diagram of an example of the sub-pixel of FIG. 2 according to an embodiment.

Referring to FIG. 3, the sub-pixel SPij may include a light emitting element LD, a first sub-pixel circuit SPC1 for controlling a light emitting time (or period) of the light emitting element LD, and a second sub-pixel circuit SPC2 for providing a driving current to the light emitting element LD.

For example, the first sub-pixel circuit SPC1 may include a first transistor T1 including a control electrode electrically connected to a first node N1, a first electrode electrically connected to a second node N2, and a second electrode electrically connected to a third node N3; a first capacitor C1 including a first electrode receiving a sweep voltage SV and a second electrode electrically connected to the first node N1; a second transistor T2 including a control electrode receiving a first write gate signal GWC1, a first electrode receiving a data voltage VDATA, and a second electrode electrically connected to the second node N2; a third transistor T3 including a control electrode receiving the first write gate signal GWC1, a first electrode electrically connected to the third node N3, and a second electrode electrically connected to the first node N1; a fourth transistor T4 including a control electrode receiving an emission signal EM, a first electrode receiving a (1-1)-th power voltage VDD1, and a second electrode electrically connected to the second node N2; a fifth transistor T5 including a control electrode receiving the emission signal EM, a first electrode electrically connected to the third node N3, and a second electrode electrically connected to the second sub-pixel circuit SPC2 (for example, a fourth node N4 of the second sub-pixel circuit SPC2); and a sixth transistor T6 including a control electrode receiving a first initialization gate signal GI1, a first electrode receiving a first initialization voltage VINT1, and a second electrode electrically connected to the first node N1.

For example, the second sub-pixel circuit SPC2 may include a seventh transistor T7 including a control electrode electrically connected to the fourth node N4, a first electrode electrically connected to a fifth node N5, and a second electrode electrically connected to a sixth node N6; a second capacitor C2 including a first electrode receiving a (1-2)-th power voltage VDD2 and a second electrode electrically connected to the fourth node N4; an eighth transistor T8 including a control electrode receiving a second write gate signal GWC2, a first electrode receiving the data voltage VDATA, and a second electrode electrically connected to the fifth node N5; a ninth transistor T9 including a control electrode receiving the second write gate signal GWC2, a first electrode electrically connected to the sixth node N6, and a second electrode electrically connected to the fourth node N4; a tenth transistor T10 including a control electrode receiving the emission signal EM, a first electrode receiving the (1-2)-th power voltage VDD2, and a second electrode electrically connected to the fifth node N5; an eleventh transistor T11 including a control electrode receiving the emission signal EM, a first electrode electrically connected to the sixth node N6, and a second electrode electrically connected to a seventh node N7; a twelfth transistor T12 including a control electrode receiving a second initialization gate signal GI2, a first electrode receiving the first initialization voltage VINT1, and a second electrode electrically connected to the fourth node N4; and a thirteenth transistor T13 including a control electrode receiving a bias gate signal BCB, a first electrode receiving a second initialization voltage VINT2, and a second electrode electrically connected to the seventh node N7.

For example, the light emitting element LD may include a first electrode (e.g., an anode electrode AE (see FIG. 2)) electrically connected to the seventh node N7 and a second electrode (e.g., a cathode electrode CE (see FIG. 2)) receiving a second power voltage VSS.

The first, fourth, fifth, seventh, tenth, eleventh, and thirteenth transistors T1, T4, T5, T7, T10, T11, and T13 may be P-type transistors, and the second, third, sixth, eighth, ninth, and twelfth transistors T2, T3, T6, T8, T9, and T12 may be N-type transistors. However, embodiments are not limited to this example. For instance, one or more of the P-type transistors may be replaced with N-type transistors, and one or more of the N-type transistors may be replaced with P-type transistors.

The sixth transistor T6 may provide the first initialization voltage VINT1 to the first node N1 in response to the first initialization gate signal GI1. A voltage of the first node N1 may be initialized to the first initialization voltage VINT1.

The second transistor T2 may provide the data voltage VDATA to the second node N2 in response to the first write gate signal GWC1. The third transistor T3 may diode-connect the first transistor T1 in response to the first write gate signal GWC1. A voltage compensated by the threshold voltage of the first transistor T1 may be provided to the first node N1.

The fourth transistor T4 may provide the first power voltage VDD1 to the first transistor T1 in response to the emission signal EM. The fifth transistor T5 may provide a first driving current generated by the first transistor T1 to the fourth node N4 in response to the emission signal EM. A time point at which the sweep voltage SV is reduced and the first transistor T1 is turned on may vary depending on a magnitude of the data voltage VDATA. A time point at which the voltage of the fourth node N4 rises may vary, and a time point at which the seventh transistor T7 is turned off may vary. For instance, the first sub-pixel circuit SPC1 may control the light emitting time (or period) of the light emitting element LD that emits light by a second driving current by adjusting the turn-off time point of the seventh transistor T7 that provides the second driving current to the light emitting element LD. A luminance of the light emitting element LD may vary depending on the light emitting time (e.g., a grayscale expression).

In embodiments, the sweep voltage SV, the second write gate signal GWC2, the emission signal EM, the bias gate signal BCB, the first initialization gate signal GI1, and the second initialization gate signal GI2 may be pixel control signals. For example, like pixel control signals may be equally provided to the sub-pixels SP (see FIG. 1).

In embodiments, the first write gate signal GWC1 may be provided to the sub-pixels SP through the first to m-th gate lines GL1 to GLm (see FIG. 1). For example, the first write gate signal GWC1 may be sequentially provided to respective gate lines GL1 to GLm (see FIG. 1).

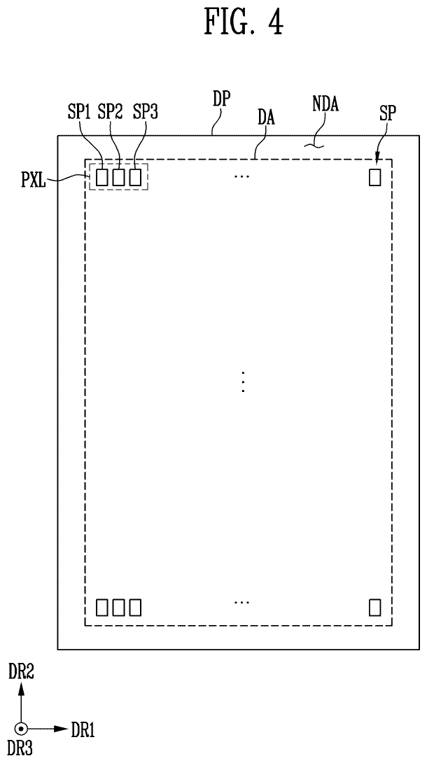

FIG. 4 schematically illustrates a top plan view of a display panel of FIG. 1 according to an embodiment.

Referring to FIG. 4, the display panel DP may include a display area DA (schematically illustrated in FIG. 4 using a dashed line representation) and a non-display area NDA. The display panel DP may display an image through the display area DA. The non-display area NDA may be disposed outside the display area DA. For instance, the non-display area NDA may be disposed around (or circumscribe) the display area DA in a plan view.

As used herein, the term “circumscribe” is not limited to a first feature forming a circle around a second feature, and as such, may include the first feature forming any suitable two-dimensional geometric figure around the second feature in a view in, for instance, the third direction DR3. A first feature being “around,” “surrounding,” or “circumscribing” a second feature may (unless otherwise specified) include an inner boundary of the first feature touching one or more points of an outer boundary of the second feature, or the inner boundary of the first feature may be spaced apart from the outer boundary of the second feature. Moreover, a first feature being “around,” “surrounding,” or “circumscribing” a second feature may include (unless otherwise specified) the first feature completely or partially being around, surrounding, or circumscribing the second feature in a view in, for instance the third direction DR3.

The display panel DP may include sub-pixels SP in the display area DA. The sub-pixels SP may be arranged along a first direction DR1 and a second direction DR2 that intersects (or is transverse to) the first direction DR1. For example, the sub-pixels SP may be arranged in a matrix format along the first direction DR1 and the second direction DR2. In some embodiments, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more of the sub-pixels SP may configure one (or a) pixel PXL, which is schematically conveyed in FIG. 4 using dashed lines around three sub-pixels SP (e.g., first to third sub-pixels SP1 to SP3) as a representation of the pixel PXL. Although FIG. 4 schematically illustrates the pixel PXL including three sub-pixels SP (e.g., first to third sub-pixels SP1 to SP3), embodiments are not limited to this example structure. For example, the pixel PXL may include two sub-pixels SP, or four or more sub-pixels SP. Hereinafter, for better understanding and ease of description, it is assumed that the pixel PXL includes the first to third sub-pixels SP1 to SP3.

Each of the first to third sub-pixels SP1 to SP3 may generate light of one of various colors such as red, green, blue, cyan, magenta, or yellow, but embodiments are not limited to this example. Hereinafter, for clear and brief description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1 to SP3 may include at least one light emitting element LD configured to generate light. In embodiments, the light emitting elements LD of the first to third sub-pixels SP1 to SP3 may generate light of a same color. For example, the light emitting elements LD of the first to third sub-pixels SP1 to SP3 may generate blue-colored light. In some embodiments, the light emitting elements LD of the first to third sub-pixels SP1 to SP3 may generate light of different colors. For example, the light emitting elements LD of the first to third sub-pixels SP1 to SP3 may generate light of red, green, and blue colors, respectively.

As the display panel DP, a self-luminous display panel, such as a light emitting diode (LED) display panel using a micro-scale or nano-scale light emitting diode as a light emitting element LD, and/or an organic light emitting diode (OLED) display panel using an organic light emitting diode as a light emitting element LD may be used. In some embodiments, a nano-scale light emitting diode may have a longitudinal dimension in a range of about 100 nm to about 10 μm, such as in a range of about 500 nm to about 5 μm. In some implementations, an aspect ratio of a nano-scale light emitting diode may be in a range of about 1 to about 100, such as in a range of about 1.2 to about 50, e.g., in a range of about 1.5 to about 20, for instance, in a range of about 1.5 to about 10. A micro-scale light emitting diode may have one or more dimensions in a range of about 10 μm to about 100 μm, such as in a range of about 50 μm to about 100 μm. However, the aforementioned dimensions are merely examples.

A constituent element to control the sub-pixels SP may be disposed in the non-display area NDA. Wires (or lines) electrically connected to the sub-pixels SP, for example, the first to m-th gate lines GL1 to GLm, the first to n-th data lines DL1 to DLn, the power lines PL, and the pixel control lines PXCL shown in FIG. 1 may be disposed in the non-display area NDA and at least some of the first to m-th gate lines GL1 to GLm, the first to n-th data lines DL1 to DLn, the power lines PL, and the pixel control lines PXCL shown in FIG. 1 may extend into the display area DA.

At least one of the gate driver 120, the data driver 130, the voltage generator 140, and the controller 150 in FIG. 1 may be disposed in the non-display area NDA of the display panel DP. In embodiments, the gate driver 120 may be disposed in the non-display area NDA. In some implementations, the data driver 130, the voltage generator 140, and the controller 150 may be implemented as the driver integrated circuit DIC of FIG. 1, which may be separate from the display panel DP, and the driver integrated circuit DIC may be electrically connected to one or more of the wires disposed in the non-display area NDA. In some embodiments, the gate driver 120 may be implemented as one (or an) integrated circuit separate from the display panel DP together with one or more of the data driver 130, the voltage generator 140, and the controller 150.

In embodiments, the display area DA may have various shapes in a plan view. For instance, the display area DA may have a closed-loop shape including sides of a straight line and/or a curved line in a plan view. For example, the display area DA may have shapes, such as at least one of a polygonal shape, a circular shape, a semicircular shape, an elliptical shape, an oval shape, and a freeform shape in a plan view.

In embodiments, the display panel DP may have a flat display surface, such as a display surface extending in a plane parallel (or substantially parallel) to a DR1-DR2 plane. In some embodiments, the display panel DP may have a display surface that is at least partially round or extending from the plane parallel (or substantially parallel) to the DR1-DR2 plane along, for instance, the third direction DR3. In embodiments, the display panel DP may be bendable, foldable, rollable, twistable, and/or flexible. Hereinafter, the terms “bendable,” “foldable,” “rollable,” “twistable,” and “flexible” may be collectively and/or individually referred to as “flexible.” The display panel DP and/or a substrate of the display panel DP may include materials with flexible properties.

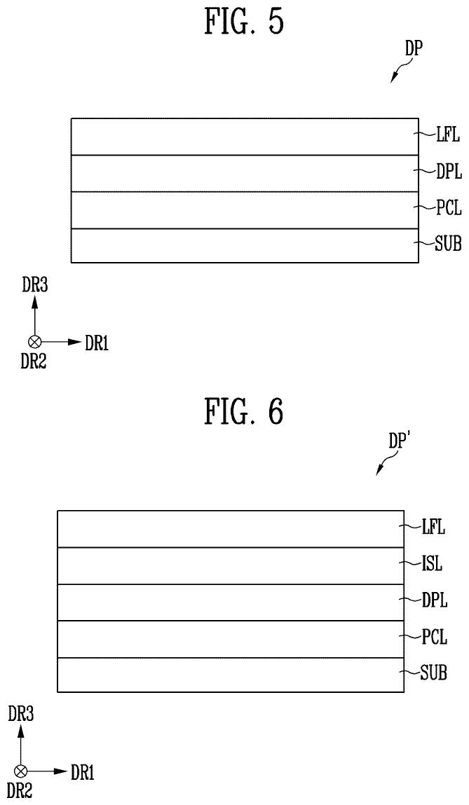

FIG. 5 schematically illustrates a cross-sectional view of a display panel of FIG. 4 according to an embodiment.

Referring to FIG. 5, the display panel DP may include a substrate SUB, and a pixel circuit layer PCL, a display element layer DPL, and a light functional layer LFL, which may be sequentially stacked on the substrate SUB in the recited order along the third direction DR3 crossing (e.g., perpendicular to) the first and second directions DR1 and DR2.

The substrate SUB may be made of an insulating material, such as at least one of glass and a resin. For example, the substrate SUB may include a glass substrate. As an example, the substrate SUB may include a polyimide (PI) substrate. As an example, the substrate SUB may include a silicon wafer substrate formed using a semiconductor process. For instance, the substrate SUB may include a semiconductor material suitable for forming circuit elements. The semiconductor material may include silicon, germanium, and/or silicon-germanium, but embodiments are not limited to these example materials. The substrate SUB may be provided from at least one of a bulk wafer, an epitaxial wafer, an epitaxial layer, a silicon on insulator (SOI) layer, and a semiconductor on insulator (SeOI) layer, but embodiments are not limited to the aforementioned examples.

In embodiments, the substrate SUB may be made of a flexible material to enable the substrate SUB to be flexible, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited to the above-noted materials.

The pixel circuit layer PCL may be disposed on the substrate SUB. The pixel circuit layer PCL may include insulating layers, semiconductor patterns, and electrically conductive patterns, which may be disposed between the insulating layers. The electrically conductive patterns of the pixel circuit layer PCL may function as circuit elements, wires, and/or the like.

The circuit elements of the pixel circuit layer PCL may include the sub-pixel circuit SPC (see FIG. 2) of each of the sub-pixels SP of FIG. 3. The circuit elements of the pixel circuit layer PCL may be provided as transistors and one or more capacitors of the sub-pixel circuit SPC.

The wires of the pixel circuit layer PCL may include wires electrically connected to the sub-pixels SP. The wires of the pixel circuit layer PCL may include various signal lines and/or voltage lines to drive the display element layer DPL.

The display element layer DPL may be disposed on the pixel circuit layer PCL. The display element layer DPL may include light emitting elements LD of the sub-pixels SP.

The light functional layer LFL may be disposed on the display element layer DPL. The light functional layer LFL may include light conversion patterns having color conversion particles and/or scattering particles. For example, the color conversion particles may include at least one of quantum dots, quantum rods, and phosphors. For convenience, an example of quantum dots will be described. The quantum dots may change the wavelength (or color) of light emitted from the display element layer DPL. For instance, the quantum dots may be particulate material that emit a specific (or selected) color as electrons transition from the conduction band to the valence band. The quantum dots may be a semiconductor nanocrystal material. The quantum dots may have a specific (or selected) bandgap depending on a composition and/or size of the quantum dots. In some embodiments, the quantum dots may absorb light and emit light with a specific (or selected) wavelength. Examples of the semiconductor nanocrystal material may include at least one of a group IV compound semiconductor nanocrystal material, a group II-VI compound semiconductor nanocrystal material, a group III-V compound semiconductor nanocrystal material, and a group IV-VI compound semiconductor nanocrystal material, but any suitable semiconductor nanocrystal material may be used as the quantum dots. The light functional layer LFL may further include light scattering patterns with scattering particles. In embodiments, the light conversion patterns and the light scattering patterns may be omitted.

The light functional layer LFL may include a color filter layer including color filters. The color filter may selectively transmit light of a specific (or selected) wavelength (or range of wavelengths) (or a specific or selected color). In embodiments, the color filter layer may be omitted.

A window for protecting an exposed surface (e.g., an upper surface) of the display panel DP may be provided on the light functional layer LFL. The window may protect the display panel DP from (or mitigate the effects of) external impact, scratches (or other abrasions), and/or influx of exogenous elements, such as moisture, debris, and/or the like. The window may be coupled to the light functional layer LFL through an optically transparent adhesive (or bonding) member. The window may have a single-layered structure or a multi-layered structure including at least one of a glass substrate, a plastic film, and a plastic substrate. The multi-layered structure may be completely or partially formed through a continuous process in which adjacent layers are formed directly on one another or an adhesive process using an adhesive layer between an adjacent layer. All or a portion of the window may be flexible.

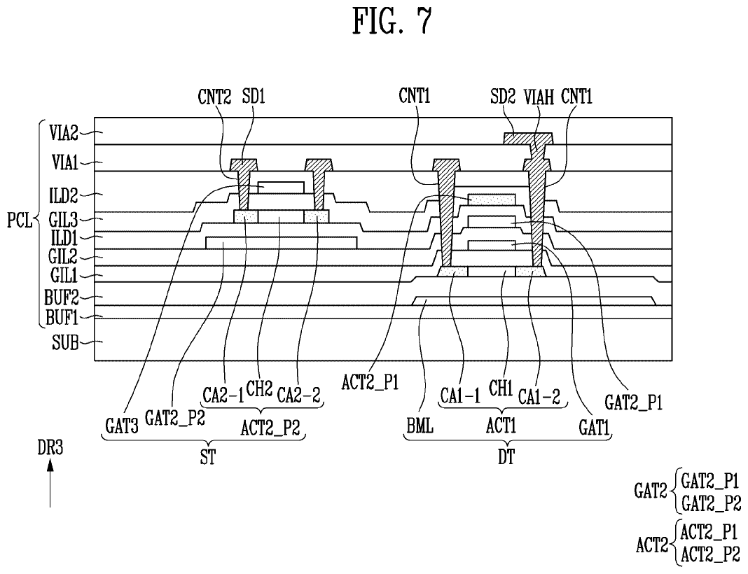

FIG. 6 schematically illustrates a cross-sectional view of a display panel of FIG. 4 according to an embodiment.

Referring to FIG. 6, a display panel DP' may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured in a same manner as the substrate SUB, the pixel circuit layer PCL, the display element layer DPL, and the light functional layer LFL described with reference to FIG. 4. Hereinafter, redundant descriptions will be omitted.

The input sensing layer ISL may detect a user input (or event) on or through a surface (e.g., an upper surface (or display surface)) of the display panel DP'. The input sensing layer ISL may include components suitable for sensing an external object, such as a user's hand (or other appendage), pen, stylus, and/or the like. For example, the input sensing layer ISL may include touch electrodes. In some embodiments, the input sensing layer ISL may be formed on or as part of the display element layer DPL through a continuous process in which adjacent layers are formed directly on one another or an adhesive process using an adhesive layer between an adjacent layer.

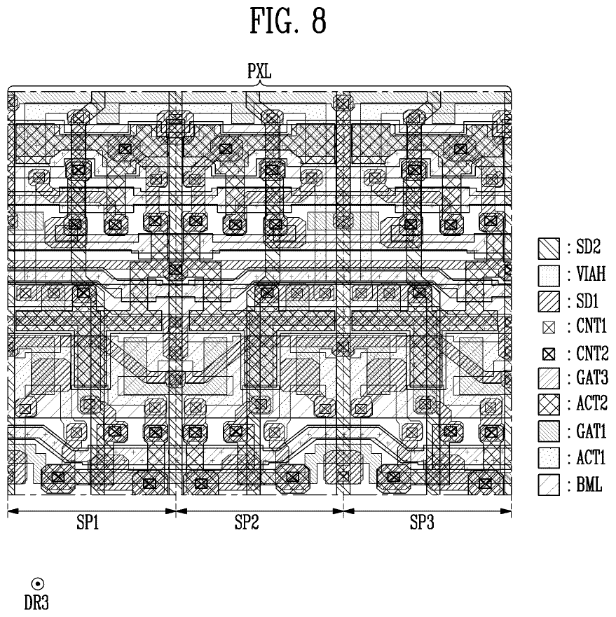

FIG. 7 schematically illustrates a cross-sectional view of an example of a substrate and a pixel circuit layer of FIG. 5 according to an embodiment.

For better comprehension and ease of description, FIG. 7 only schematically illustrates configurations of a driving transistor DT and a switching transistor ST, but configurations of transistors other than the driving transistor DT and the switching transistor ST, a configuration for electrically connecting transistors, and a configuration for electrically connecting the light emitting element LD (see FIG. 3) and a transistor are omitted. The driving transistor DT may be a transistor that generates a driving current, and the switching transistor ST may be a transistor except for a light emitting control transistor that controls light emission and a transistor (for example, the thirteenth transistor T13 (see FIG. 3)) for initializing the light emitting element LD (see FIG. 3), among transistors for controlling the driving transistor DT to generate the driving current. For example, in FIG. 3, the first and seventh transistors T1 and T7 may be examples of the driving transistor DT, the second, third, sixth, eighth, ninth, and twelfth transistors T2, T3, T6, T8, T9, and T12 may be examples of a switching transistor ST, and the fourth, fifth, tenth, and eleventh transistors T4, T5, T10, and T11 may be examples of a light emitting control transistors.

Referring to FIG. 3 and FIG. 7, the pixel circuit layer PCL may include a first buffer layer BUF1, a lower electrode layer BML, a second buffer layer BUF2, a first active layer ACT1, a first gate insulating layer GIL1, a first electrode layer GAT1, a second gate insulating layer GIL2, a first interlayer insulating layer ILD1, a second active layer ACT2, a third gate insulating layer GIL3, a third electrode layer GAT3, a second interlayer insulating layer ILD2, a first connection electrode layer SD1, a first via layer VIA1, a second connection electrode layer SD2, and a second via layer VIA2.

The first buffer layer BUF1 may be disposed on one (or a) surface of the substrate SUB. The first buffer layer BUF1 may prevent (or mitigate) impurities from diffusing into the circuit elements and/or wires included in the pixel circuit layer PCL. The first buffer layer BUF1 may include an inorganic insulating layer including an inorganic material. In embodiments, the first buffer layer BUF1 may include at least one of metal oxides, such as at least one of a silicon nitride (SiNx), a silicon oxide (SiOx), a silicon oxynitride (SiOxNy), and an aluminum oxide (AlOx), but embodiments are not limited to these example materials. The first buffer layer BUF1 may be provided as a single layer or multiple layers. In a case that the first buffer layer BUF1 is provided as multiple layers, respective layers of the first buffer layer BUF1 may be made of a same material or different materials.

In embodiments, one or more barrier layers may be disposed between the substrate SUB and the first buffer layer BUF1. Each of the barrier layers may include polyimide, but embodiments are not limited to polyimide.

The driving transistor DT may be disposed on the first buffer layer BUF1. The driving transistor DT may be one of the first transistor T1 and the seventh transistor T7. The driving transistor DT may include the lower electrode layer BML, the first active layer ACT1, and the first electrode layer GAT1.

The lower electrode layer BML may be disposed on the first buffer layer BUF1. The lower electrode layer BML may form a back, lower, or second gate electrode of the driving transistor DT. Hereinafter, the back, lower, or second gate electrode of the driving transistor DT will be referred to as a back gate electrode. For example, the lower electrode layer BML may be disposed under the first active layer ACT1 such that the lower electrode layer BML may be disposed between the first active layer ACT1 and the substrate SUB along the third direction DR3. For example, the lower electrode layer BML may be formed as a conductive pattern including at least one material of copper (Cu), molybdenum (Mo), tungsten (W), aluminum neodymium (AlNd), titanium (Ti), aluminum (Al), and silver (Ag), but embodiments are not limited to these example materials.

In embodiments, a portion of the lower electrode layer BML forming the back gate electrode of the first transistor T1 may be electrically connected to the (1-1)-th power voltage VDD1, and a portion of the lower electrode layer BML forming the back gate electrode of the seventh transistor T7 may be electrically connected to the (1-2)-th power voltage VDD2.

The second buffer layer BUF2 may be disposed on the first buffer layer BUF1 and the lower electrode layer BML. The second buffer layer BUF2 may prevent (or mitigate) impurities from diffusing into the circuit elements and/or wires included in the pixel circuit layer PCL. The second buffer layer BUF2 may include an inorganic insulating layer including an inorganic material. In embodiments, the second buffer layer BUF2 may include at least one of metal oxides, such as at least one of a silicon nitride (SiNx), a silicon oxide (SiOx), a silicon oxynitride (SiOxNy), and an aluminum oxide (AlOx), but embodiments are not limited to these example materials. The second buffer layer BUF2 may be provided as a single layer or multiple layers. In a case that the second buffer layer BUF2 is provided as multiple layers, respective layers of the second buffer layer BUF2 may be made of a same material or different materials.

The first active layer ACT1 may be disposed on the second buffer layer BUF2. The first active layer ACT1 may include a (1-1)-th contact area CA1-1 and a (1-2)-th contact area CA1-2 electrically connected to the first connection electrode layer SD1. The (1-1)-th contact area CA1-1 and the (1-2)-th contact area CA1-2 may be electrically connected to the first connection electrode layer SD1 through contact holes, such as the first contact hole CNT1. In some embodiments, the (1-2)-th contact area CA1-2 may be electrically connected to the second connection electrode layer SD2 through the first contact hole CNT1 and the via hole VIAH.

An area between the (1-1)-th contact area CA1-1 and the (1-2)-th contact area CA1-2 may be a first channel area CH1. The first channel area CHI may overlap, along the third direction DR3, the first electrode layer GAT1 forming the control electrode of the driving transistor DT. The first channel area CHI may be a semiconductor pattern that is not doped with impurities, and may be an intrinsic semiconductor. The (1-1)-th contact area CA1-1 and the (1-2)-th contact area CA1-2 may be semiconductor patterns doped with impurities.

The first active layer ACT1 may include at least one of various types of semiconductors, for example, at least one of an amorphous silicon semiconductor, a monocrystalline silicon semiconductor, a polycrystalline silicon semiconductor, a low temperature polysilicon semiconductor, and an oxide semiconductor.

The first gate insulating layer GIL1 may be disposed on the second buffer layer BUF2 and the first active layer ACT1. The first gate insulating layer GIL1 may be an inorganic insulating layer including an inorganic material. For example, the first gate insulating layer GIL1 may include at least one of metal oxides, such as at least one of a silicon nitride (SiNx), a silicon oxide (SiOx), a silicon oxynitride (SiOxNy), and an aluminum oxide (AlOx). However, the first gate insulating layer GIL1 is not limited to the above-noted example materials. For example, the first gate insulating layer GIL1 may include an organic insulating layer including an organic material.

The first gate insulating layer GIL1 may electrically separate (or electrically insulate) electrically conductive patterns and/or semiconductor patterns disposed with the first gate insulating layer GIL1 disposed between the electrically conductive patterns and/or semiconductor patterns. As used herein, the phrases “electrically separate” and “electrically insulate” may refer to the deliberate introduction of an electrically non-conductive separation between electrically conductive elements to prevent the transfer of direct current and unwanted alternating current between at least two electrically conductive elements. For instance, electrically separating or electrically isolating two electrically conductive elements may mean that a direct electrical conduction path is not provided between the two electrically conductive elements. The first gate insulating layer GIL1 may be disposed between the first active layer ACT1 and the first electrode layer GAT1 so that the first electrode layer GAT1 is spaced apart from the first active layer ACT1 in the third direction DR3. In embodiments, the first gate insulating layer GIL1 may be provided on (e.g., entirely on) the first active layer ACT1 and the second buffer layer BUF2 to cover (or overlap) the first active layer ACT1 and the second buffer layer BUF2.

The first electrode layer GAT1 may be disposed on the first gate insulating layer GIL1. The first electrode layer GAT1 may form the control electrode of the driving transistor DT. The first electrode layer GAT1 may overlap the first channel area CHI of the first active layer ACT1 in the third direction DR3. In embodiments, the first electrode layer GAT1 may be provided as a single layer including at least one of copper (Cu), molybdenum (Mo), tungsten (W), aluminum neodymium (AlNd), titanium (Ti), aluminum (Al), and silver (Ag), but embodiments are not limited to these example materials. In embodiments, the first electrode layer GAT1 may be provided as a multilayer structure including at least one of molybdenum (Mo), titanium (Ti), aluminum (Al), and silver (Ag), which are relatively low-resistance materials, but other materials may be utilized.

The second gate insulating layer GIL2 may be disposed on the first gate insulating layer GIL1 and the first electrode layer GAT1. The second gate insulating layer GIL2 may be AN inorganic insulating layer including an inorganic material. For example, the second gate insulating layer GIL2 may include at least one of metal oxides, such as at least one of a silicon nitride (SiNx), a silicon oxide (SiOx), a silicon oxynitride (SiOxNy), and an aluminum oxide (AlOx). However, the second gate insulating layer GIL2 is not limited to the above-noted example materials. For example, the second gate insulating layer GIL2 may include an organic insulating layer including an organic material.

The second gate insulating layer GIL2 may electrically separate electrically conductive patterns and/or semiconductor patterns disposed with the second gate insulating layer GIL2 disposed between the electrically conductive patterns and/or semiconductor patterns. For example, the second gate insulating layer GIL2 may be disposed between the second electrode layer GAT2 and the first electrode layer GAT1 so that the second electrode layer GAT2 is spaced apart from the first electrode layer GAT1 in the third direction DR3. In embodiments, the second gate insulating layer GIL2 may be provided on (e.g., entirely on) the first electrode layer GAT1 and the first gate insulating layer GIL1 to cover the first electrode layer GAT1 and the first gate insulating layer GIL1.

The switching transistor ST may be disposed on the second gate insulating layer GIL2. The switching transistor ST may be one of the second, third, sixth, eighth, ninth, and twelfth transistors T2, T3, T6, T8, T9, and T12. The switching transistor ST may include a second portion GAT2_P2 of the second electrode layer GAT2, a second portion ACT2_P2 of the second active layer ACT2, and the third electrode layer GAT3.

The second electrode layer GAT2 may be disposed on the second gate insulating layer GIL2. In embodiments, the second electrode layer GAT2 may be provided as a single layer including at least one of copper (Cu), molybdenum (Mo), tungsten (W), aluminum neodymium (AlNd), titanium (Ti), aluminum (Al), and silver (Ag), but embodiments are not limited to these example materials. In embodiments, the second electrode layer GAT2 may be provided as a multilayer structure including at least one of molybdenum (Mo), titanium (Ti), aluminum (Al), and silver (Ag), which are relatively low-resistance materials, but other materials may be utilized.

The second electrode layer GAT2 may include a first portion GAT2_P1 disposed on the first electrode layer GAT1 to overlap the first electrode layer GAT1 in the third direction DR3. The first portion GAT2_P1 of the second electrode layer GAT2 may form one (or an) electrode of a capacitor. The capacitor may include at least one of the first capacitor C1 and the second capacitor C2. For example, the sweep voltage SV may be applied to the first portion GAT2_P1 of the second electrode layer GAT2 forming an electrode of the first capacitor C1, and the (1-2)-th power voltage VDD2 may be applied to the first portion GAT2_P1 of the second electrode layer GAT2 forming an electrode of the second capacitor C2. The first portion GAT2_P1 of the second electrode layer GAT2 may overlap the first electrode layer GAT1 in the third direction DR3.

The second electrode layer GAT2 may include the second portion GAT2_P2 disposed below the second portion ACT2_P2 of the second active layer ACT2 in the third direction DR3. For example, the second portion GAT2_P2 of the second electrode layer GAT2 may form the back gate electrode of the switching transistor ST. In embodiments, the first write gate signal GWC1 may be applied to the second portion GAT2_P2 of the second electrode layer GAT2 forming the back gate electrode of the second transistor T2 and the back gate electrode of the third transistor T3. In an embodiment, the first initialization gate signal GI1 may be applied to the second portion GAT2_P2 of the second electrode layer GAT2 forming the back gate electrode of the sixth transistor T6. In an embodiment, the second write gate signal GWC2 may be applied to the second portion GAT2_P2 of the second electrode layer GAT2 forming the back gate electrode of the eighth transistor T8 and the back gate electrode of the ninth transistor T9.

The first interlayer insulating layer ILD1 may be disposed on the second gate insulating layer GIL2 and the second electrode layer GAT2. The first interlayer insulating layer ILD1 may be an inorganic insulating layer including an inorganic material. For example, the first interlayer insulating layer ILD1 may include at least one of metal oxides, such as at least one of a silicon nitride (SiNx), a silicon oxide (SiOx), a silicon oxynitride (SiOxNy), and an aluminum oxide (AlOx). However, the first interlayer insulating layer ILD1 is not limited to the above-noted example materials. For example, the first interlayer insulating layer ILD1 may include an organic insulating layer including an organic material.

The first interlayer insulating layer ILD1 may electrically separate electrically conductive patterns and/or semiconductor patterns disposed with the first interlayer insulating layer ILD1 between the electrically conductive patterns and/or semiconductor patterns. For example, the first interlayer insulating layer ILD1 may be disposed between the second electrode layer GAT2 and the second active layer ACT2 so that the second electrode layer GAT2 is spaced apart from the second active layer ACT2 in the third direction DR3. In embodiments, the first interlayer insulating layer ILD1 may be provided on (e.g., entirely on) the second electrode layer GAT2 and the second gate insulating layer GIL2 to cover the second electrode layer GAT2 and the second gate insulating layer GIL2.

The second active layer ACT2 may be disposed on the first interlayer insulating layer ILD1. The second active layer ACT2 may include at least one of various types of semiconductors, for example, at least one of an amorphous silicon semiconductor, a monocrystalline silicon semiconductor, a polycrystalline silicon semiconductor, a low temperature polysilicon semiconductor, and an oxide semiconductor, but embodiments are not limited to these example materials.

The second active layer ACT2 may include a first portion ACT2_P1 disposed to overlap, along the third direction DR3, the first portion GAT2_P1 of the second electrode layer GAT2 on the first portion GAT2_P1 of the second electrode layer GAT2. The first portion ACT2_P1 of the second active layer ACT2 may be a semiconductor pattern doped with an impurity. The first portion ACT2_P1 of the second active layer ACT2 may form a capacitor. For example, the capacitor (for example, at least one of the first capacitor Cl and the second capacitor C2) may be formed of the first electrode layer GAT1, the first portion GAT2_P1 of the second electrode layer GAT2, and the first portion ACT2_P1 of the second active layer ACT2. At least because the first portion ACT2_P1 of the second active layer ACT2 is utilized as a capacitor, a greater capacitance may be secured.

The second active layer ACT2 may include a second portion ACT2_P2 including the second channel area CH2 of the switching transistor ST. The second portion ACT2_P2 of the second active layer ACT2 may include a (2-1)-th contact area CA2-1 and a (2-2)-th contact area CA2-2 electrically connected to the first connection electrode layer SD1. The (2-1)-th contact area CA2-1 and the (2-2)-th contact area CA2-2 may be electrically connected to the first connection electrode layer SD1 through contact holes, e.g., the second contact hole CNT2.

An area between the (2-1)-th contact area CA2-1 and the (2-2)-th contact area CA2-2 may be a second channel area CH2. The second channel area CH2 may overlap the third electrode layer GAT3 forming the control electrode of the switching transistor ST in the third direction DR3. The second channel area CH2 may be a semiconductor pattern that is not doped with impurities, and may be an intrinsic semiconductor. The (2-1)-th contact area CA2-1 and the (2-2)-th contact area CA2-2 may be semiconductor patterns doped with impurities.

The third gate insulating layer GIL3 may be disposed on the first interlayer insulating layer ILD1 and the second active layer ACT2. The third gate insulating layer GIL3 may be an inorganic insulating layer including an inorganic material. For example, the third gate insulating layer GIL3 may include at least one of metal oxides, such as at least one of a silicon nitride (SiNx), a silicon oxide (SiOx), a silicon oxynitride (SiOxNy), and an aluminum oxide (AlOx). However, the third gate insulating layer GIL3 is not limited to the above-noted example materials. For example, the third gate insulating layer GIL3 may include an organic insulating layer including an organic material.

The third gate insulating layer GIL3 may electrically separate electrically conductive patterns and/or semiconductor patterns disposed with the third gate insulating layer GIL3 between the electrically conductive patterns and/or semiconductor patterns. For example, the third gate insulating layer GIL3 may be disposed between the second active layer ACT2 and the third electrode layer GAT3 so that the second active layer ACT2 is spaced apart from the third electrode layer GAT3 in the third direction DR3. In embodiments, the third gate insulating layer GIL3 may be provided on (e.g., entirely on) the second active layer ACT2 and the first interlayer insulating layer ILD1 to cover the second active layer ACT2 and the first interlayer insulating layer ILD1.

The third electrode layer GAT3 may be disposed on the third gate insulating layer GIL3. The third electrode layer GAT3 may not overlap the first portion ACT2_P1 of the second active layer ACT2 in the third direction DR3, but may overlap the second portion ACT2_P2 of the second active layer ACT2 in the third direction DR3. In embodiments, the third electrode layer GAT3 may be provided as a single layer including at least one of copper (Cu), molybdenum (Mo), tungsten (W), aluminum neodymium (AlNd), titanium (Ti), aluminum (Al), and silver (Ag), but embodiments are not limited to these example materials. In embodiments, the third electrode layer GAT3 may be provided as a multilayer structure including at least one of molybdenum (Mo), titanium (Ti), aluminum (Al), and silver (Ag), which are relatively low-resistance materials, but other materials may be utilized.

The second interlayer insulating layer ILD2 may be disposed on the third gate insulating layer GIL3 and the third electrode layer GAT3. The second interlayer insulating layer ILD2 may be an inorganic insulating layer including an inorganic material. For example, the second interlayer insulating layer ILD2 may include at least one of metal oxides, such as at least one of a silicon nitride (SiNx), a silicon oxide (SiOx), a silicon oxynitride (SiOxNy), and an aluminum oxide (AlOx). However, the second interlayer insulating layer ILD2 is not limited to the above-noted example materials. For example, the second interlayer insulating layer ILD2 may include an organic insulating layer including an organic material.

The second interlayer insulating layer ILD2 may electrically separate electrically conductive patterns and/or semiconductor patterns disposed with the second interlayer insulating layer ILD2 between the electrically conductive patterns and/or semiconductor patterns. For example, the second interlayer insulating layer ILD2 may be disposed between the third electrode layer GAT3 and the first connection electrode layer SD1 so that the third electrode layer GAT3 is spaced apart from the first connection electrode layer SD1 in the third direction DR3. In embodiments, the second interlayer insulating layer ILD2 may be provided on (e.g., entirely on) the third gate insulating layer GIL3 and the third electrode layer GAT3 to cover the third gate insulating layer GIL3 and the third electrode layer GAT3.

The first connection electrode layer SD1 is disposed on the second interlayer insulating layer ILD2. The first connection electrode layer SD1 may be electrically connected to the first active layer ACT1 through contact holes, such as the first contact hole CNT1. In embodiments, the first connection electrode layer SD1 may be electrically connected to the first electrode layer GAT1 through the first contact hole CNT1. The first connection electrode layer SD1 may be electrically connected to the second active layer ACT2 through contact holes, such as the second contact hole CNT2.

The first and second via layers VIA1 and VIA2 may be disposed on the first connection electrode layer SD1. The first and second via layers VIA1 to VIA2 may electrically separate the first and second connection electrode layers SD1 and SD2 from each other. In some implementations, the first and second connection electrode layers SD1 and SD2 may be electrically connected to each other through a via hole VIAH. For example, the second connection electrode layer SD2 may be electrically connected to the first connection electrode layer SD1 through the via hole VIAH. In some embodiments, at least one of the first and second connection electrode layers SD1 and SD2 may be electrically connected to the light emitting element LD through the via hole VIAH.

The first and second connection electrode layers SD1 and SD2 may include at least one of copper (Cu), molybdenum (Mo), tungsten (W), aluminum neodymium (AlNd), titanium (Ti), copper (Cu), aluminum (Al), and silver (Ag), but embodiments are not limited to these example materials.

Although it is illustrated in FIG. 7 that there are two via layers (e.g., first and second via layers VA1 and VIA2) and two connection electrode layers (e.g., first and second connection electrode layers SD1 and SD2), embodiments are not limited to the illustrated number of via layers and connection electrode layers.

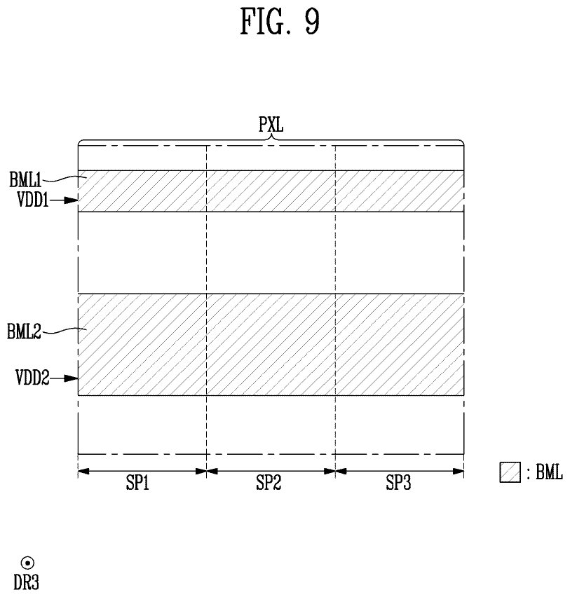

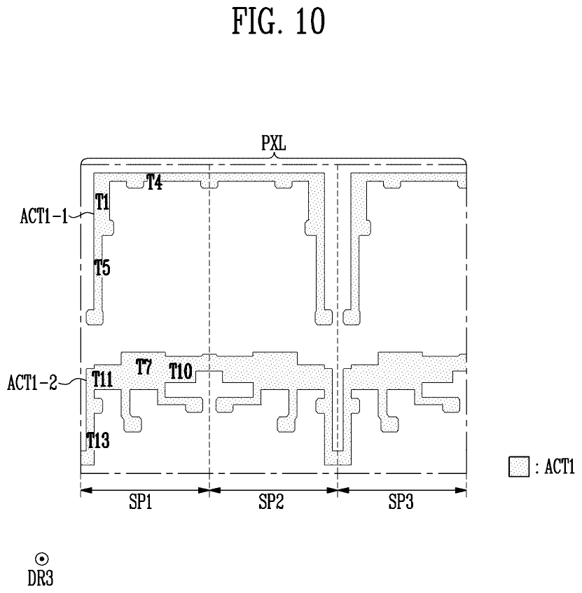

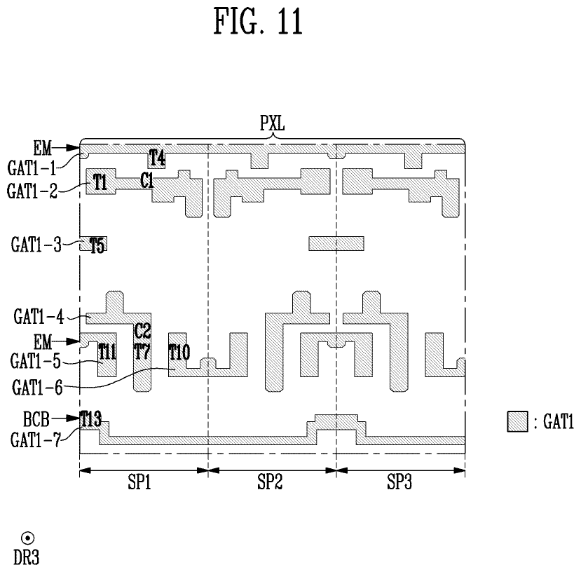

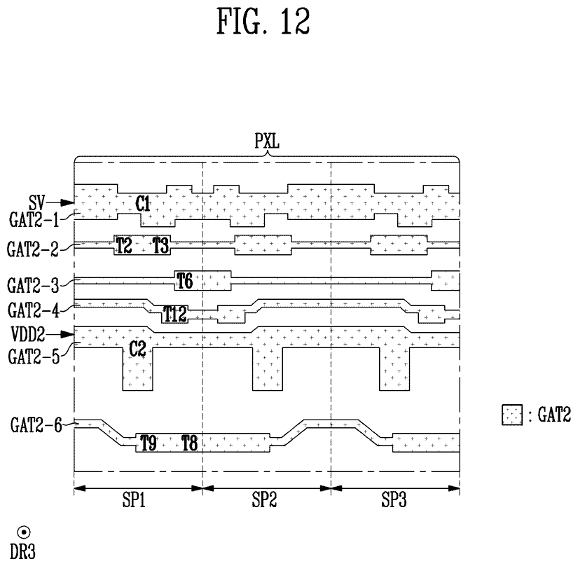

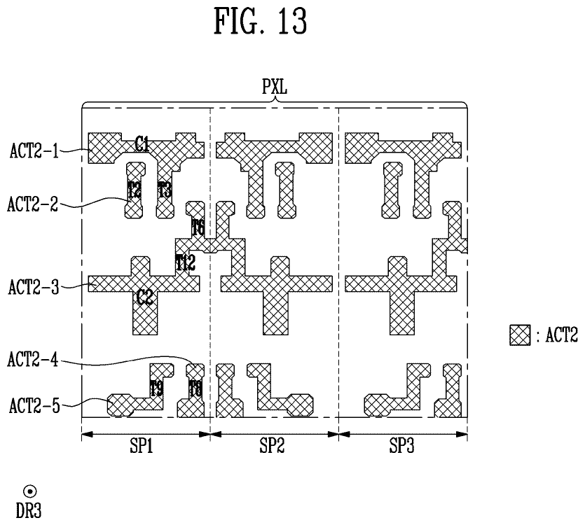

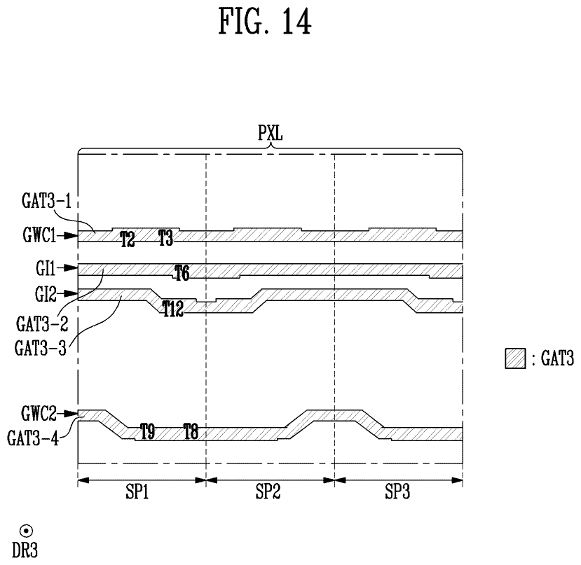

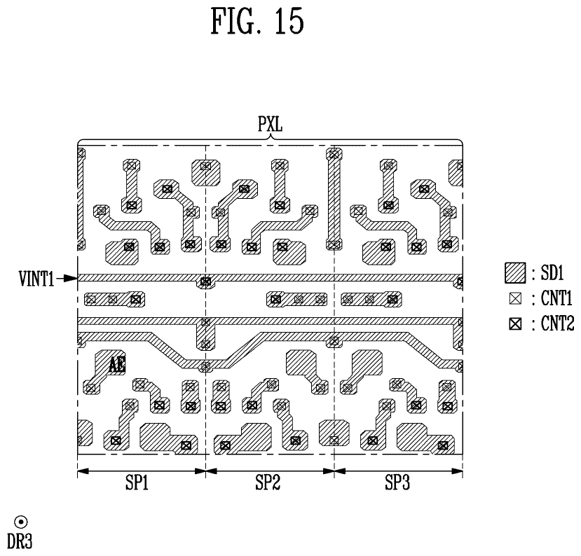

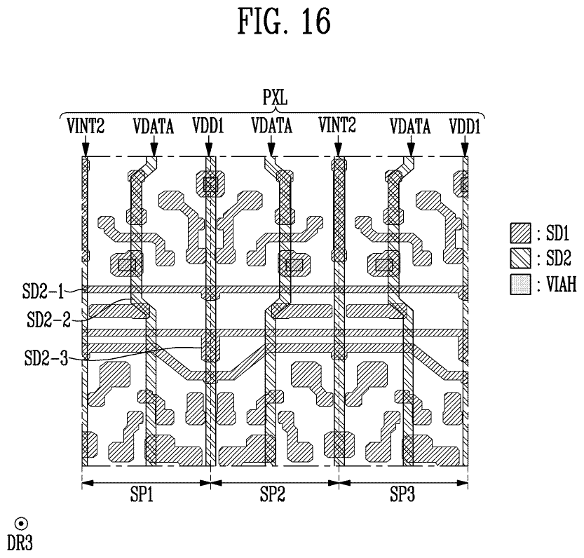

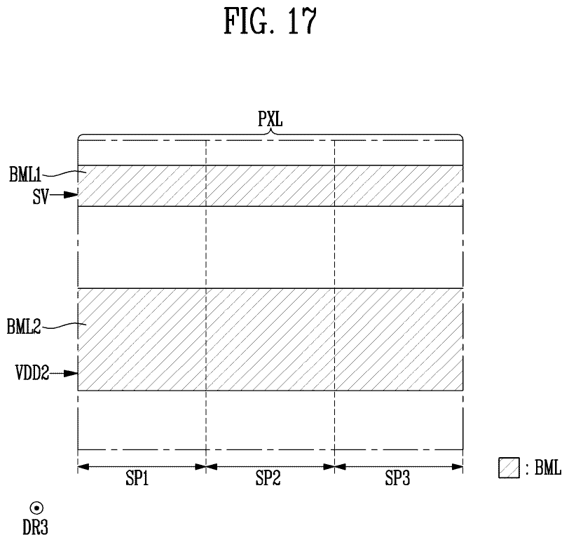

FIG. 8 schematically illustrates a layout view of an example of a pixel PXL of FIG. 1 according to an embodiment. FIG. 9 schematically illustrates a layout view of a lower electrode layer of FIG. 8 according to an embodiment. FIG. 10 schematically illustrates a layout view of a first active layer of FIG. 8 according to an embodiment. FIG. 11 schematically illustrates a layout view of a first electrode layer of FIG. 8 according to an embodiment. FIG. 12 schematically illustrates a layout view of a second electrode layer of FIG. 8 according to an embodiment. FIG. 13 schematically illustrates a layout view of a second active layer of FIG. 8 according to an embodiment. FIG. 14 schematically illustrates a layout view of a third electrode layer of FIG. 8 according to an embodiment. FIG. 15 schematically illustrates a layout view of a first connection electrode layer, a first contact hole, and a second contact hole of FIG. 8 according to an embodiment. FIG. 16 schematically illustrates a layout view of a first connection electrode layer, a second connection electrode layer, and a via hole of FIG. 8 according to an embodiment.

Referring to FIG. 8, adjacent sub-pixels may have a mirror structure or mirror symmetry about respective lines of symmetry. For example, as shown in FIG. 8, the first sub-pixel SP1 and the second sub-pixel SP2 may exhibit mirror symmetry about a first line of symmetry illustrated as a dashed line between the first sub-pixel SP1 and the second sub-pixel SP2, and the second sub-pixel SP2 and the third sub-pixel SP3 may exhibit mirror symmetry about a second line of symmetry illustrated as a dashed line between the second sub-pixel SP2 and the third sub-pixel SP3.

Referring to FIG. 8 and FIG. 9, the lower electrode layer BML may include a first lower conductive pattern BML1 and a second lower conductive pattern BML2. The first and second lower conductive patterns BML1 and BML2 may be disposed on a same layer as one another and may include a same material as one another. The first lower conductive pattern BML1 may form the back gate electrode of the first transistor T1, and the second lower conductive pattern BML2 may form the back gate electrode of the seventh transistor T7. In some embodiments, the (1-1)-th power voltage VDD1 may be applied to the first lower conductive pattern BML1, and the (1-2)-th power voltage VDD2 may be applied to the second lower conductive pattern BML2.

Referring to FIG. 8 and FIG. 10, the first active layer ACT1 may include a (1-1)-th active pattern ACT1-1 and a (1-2)-th active pattern ACT1-2. The (1-1)-th active pattern ACT1-1 and the (1-2)-th active pattern ACT1-2 may be disposed on a same layer as one another. The (1-1)-th active pattern ACT1-1 may form the channel areas of the first, fourth, and fifth transistors T1, T4, and T5. The (1-2)-th active pattern ACT1-2 may form the channel areas of the seventh, tenth, eleventh, and thirteenth transistors T7, T10, T11, and T13.

Referring to FIG. 8 and FIG. 11, the first electrode layer GAT1 may include (1-1)-th to (1-7)-th conductive patterns GAT1-1 to GAT1-7. The (1-1)-th to (1-7)-th conductive patterns GAT1-1 to GAT1-7 may be disposed on a same layer as one another and may include a same material as one another. The (1-1)-th conductive pattern GAT1-1 may form the control electrode of the fourth transistor T4. The (1-2)-th conductive pattern GAT1-2 may form the control electrode of the first transistor T1 and a portion of the first capacitor C1. The (1-3)-th conductive pattern GAT1-3 may form the control electrode of the fifth transistor T5. The (1-4)-th conductive pattern GAT1-4 may form a portion of the second capacitor C2 and the control electrode of the seventh transistor T7. The (1-5)-th conductive pattern GAT1-5 may form the control electrode of the eleventh transistor T11. The (1-6)-th conductive pattern GAT1-6 may form the control electrode of the tenth transistor T10. The (1-7)-th conductive pattern GAT1-7 may form the control electrode of the thirteenth transistor T13. In some embodiments, the emission signal EM may be applied to the (1-1)-th conductive pattern GAT1-1 and the (1-5)-th conductive pattern GAT1-5, and the bias gate signal BCB may be applied to the (1-7)-th conductive pattern GAT1-7.

Referring to FIG. 8 and FIG. 12, the second electrode layer GAT2 may include (2-1)-th to (2-6)-th conductive patterns GAT2-1 to GAT2-6. The (2-1)-th to (2-6)-th conductive patterns GAT2-1 to GAT2-6 may be disposed on a same layer as one another and may include a same material as one another. The (2-1)-th conductive pattern GAT2-1 may form a portion of the first capacitor C1, and in some embodiments, the sweep voltage SV may be applied to the (2-1)-th conductive pattern GAT2-1. The (2-2)-th conductive pattern GAT2-2 may form the back gate electrodes of the second and third transistors T2 and T3. The (2-3)-th conductive pattern GAT2-3 may form the back gate electrode of the sixth transistor T6. The (2-4)-th conductive pattern GAT2-4 may form the back gate electrode of the twelfth transistor T12. The (2-5)-th conductive pattern GAT2-5 may form a portion of the second capacitor C2. In some embodiments, the (1-2)-th power voltage VDD2 may be applied to the (2-5)-th conductive pattern GAT2-5. The (2-6)-th conductive pattern GAT2-6 may form the back gate electrodes of the eighth and ninth transistors T8 and T9.

Referring to FIG. 8 and FIG. 13, the second active layer ACT2 may include (2-1)-th to (2-5)-th active patterns ACT2-1 to ACT2-5. The (2-1)-th to (2-5)-th active patterns ACT2-1 to ACT2-5 may be disposed on a same layer as one another. The (2-1)-th active pattern ACT2-1 may form a portion of the first capacitor C1 and the channel area of the third transistor T3. The (2-2) active pattern ACT2-2 may form the channel area of the second transistor T2. The (2-3)-th active pattern ACT2-3 may form a portion of the second capacitor C2, the channel area of the sixth transistor T6, and the channel area of the twelfth transistor T12. The (2-4)-th active pattern ACT2-4 may form the channel area of the eighth transistor T8. The (2-5)-th active pattern ACT2-5 may form the channel area of the ninth transistor T9.

Referring to FIG. 8 and FIG. 14, the third electrode layer GAT3 may include (3-1)-th to (3-4)-th conductive patterns GAT3-1 to GAT3-4. The (3-1)-th to (3-4)-th conductive patterns GAT3-1 to GAT3-4 may be disposed on a same layer as one another and may include a same material as one another. The (3-1)-th conductive pattern GAT3-1 may form the control electrodes of the second and third transistors T2 and T3, and in some embodiments, the first write gate signal GWC1 may be applied to the (3-1)-th conductive pattern GAT3-1. The (3-2)-th conductive pattern GAT3-2 may form the control electrode of the sixth transistor T6, and in some embodiments, the first initialization gate signal GI1 may be applied to the (3-2)-th conductive pattern GAT3-2. The (3-3)-th conductive pattern GAT3-3 may form the control electrode of the twelfth transistor T12, and in some embodiments, the second initialization gate signal GI2 may be applied to the (3-3)-th conductive pattern GAT3-3. The (3-4)-th conductive pattern GAT3-4 may form the control electrodes of the eighth and ninth transistors T8 and T9, and in some embodiments, the second write gate signal GWC2 may be applied to the (3-4)-th conductive pattern GAT3-4.

Referring to FIG. 8 and FIG. 15, the first connection electrode layer SD1 may include various conductive patterns. The first contact hole CNT1 may electrically connect the first connection electrode layer SD1 to the first active layer ACT1 or the first electrode layer GAT1. The second contact hole CNT2 may electrically connect the first connection electrode layer SD1 to the second active layer ACT2. The first initialization voltage VINT1 may be applied to some of the conductive patterns of the first connection electrode layer SD1.

Referring to FIG. 8 and FIG. 16, the second connection electrode layer SD2 may include (4-1)-th to (4-3)-th conductive patterns SD2-1 to SD2-3. The second initialization voltage VINT2 may be applied to the (4-1)-th conductive pattern SD2-1. The data voltage VDATA may be applied to the (4-2)-th conductive pattern SD2-2. The (1-1)-th power voltage VDD1 may be applied to the (4-3)-th conductive pattern SD2-3. The (4-1)-th conductive pattern SD2-1 and the (4-3)-th conductive pattern SD2-3 may be shared by adjacent sub-pixels disposed on respectively opposing sides of the (4-1)-th conductive pattern SD2-1 and the (4-3)-th conductive pattern SD2-3.

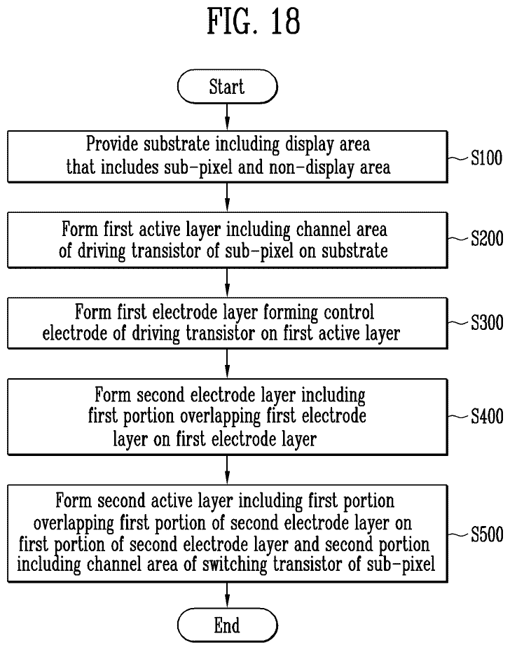

FIG. 17 schematically illustrates an example of a lower electrode layer of a display device according to an embodiment.

The display device shown in FIG. 17 is substantially similar to the configuration of the display device described in conjunction with FIGS. 8 and 9, except for the lower electrode layer BML and application of sweep voltage SV and (1-2)-th power voltage VDD2, and the same reference numbers and reference symbols are used for the same or similar components, and redundant descriptions are omitted.

Referring to FIG. 12 and FIG. 17, at least a portion of the lower electrode layer BML may be electrically connected to the first portion GAT2_P1 of the second electrode layer GAT2. In embodiments, at least a portion of the lower electrode layer BML may be electrically connected in the non-display area NDA (see FIG. 4). At least a portion of the lower electrode layer BML may be electrically connected to the first portion GAT2_P1 of the second electrode layer GAT2 so that a greater capacitance may be secured.

In some implementations, the sweep voltage SV may be applied to the first lower conductive pattern BML1 and the (2-1)-th conductive pattern GAT2-1. The (1-2)-th power voltage VDD2 may be applied to the second lower conductive pattern BML2 and the (2-5)-th conductive pattern GAT2-5.

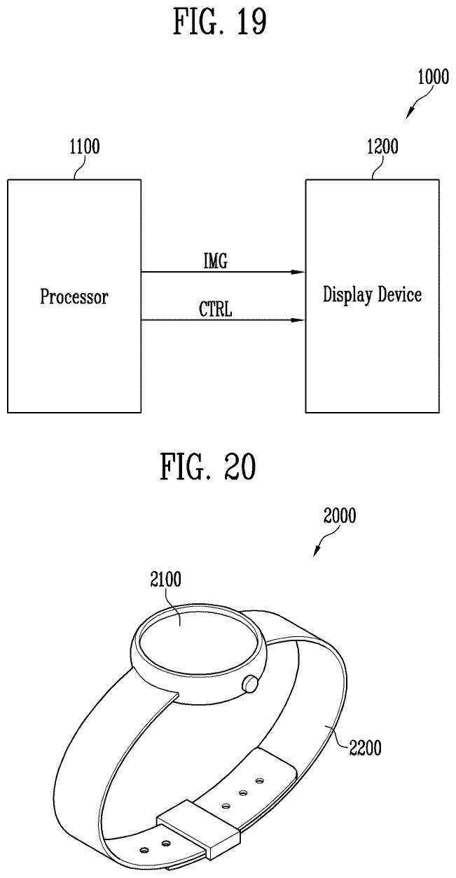

FIG. 18 schematically illustrates a flowchart of a method of manufacturing a display device according to embodiments of the present disclosure. To facilitate an understanding, the method of manufacturing the display device will be described in association with the features shown in FIGS. 4 and 7.

Referring to FIG. 18, a method of manufacturing a display device may include providing a substrate SUB including a display area DA that includes a sub-pixel SP and a non-display area NDA (S100); forming a first active layer ACT1 including a channel area CH1 of a driving transistor DT of the sub-pixel SP on the substrate SUB (S200); forming a first electrode layer GAT1 forming a control electrode of the driving transistor DT on the first active layer ACT1 (S300); forming a second electrode layer GAT2 including a first portion GAT2_P1 overlapping, in a direction perpendicular to the substrate SUB, the first electrode layer GAT1 on the first electrode layer GAT1 (S400); and forming a second active layer ACT2 including a first portion ACT2_P1 overlapping, in a direction perpendicular to the substrate SUB, the first portion GAT2_P1 of the second electrode layer GAT2 on the first portion GAT2 P1 of the second electrode layer GAT2 and a second portion ACT2_P2 including a channel area CH2 of a switching transistor ST of the sub-pixel SP (S500). In embodiments, the method of manufacturing the display device may form a third electrode layer GAT3 forming the control electrode of the switching transistor ST. In some embodiments, in the method of manufacturing the display device, the lower electrode layer BML may be formed on the substrate SUB, and at least a portion of the lower electrode layer BML may be electrically connected to the first portion GAT2-P1 of the second electrode layer GAT2.

According to various embodiments, a capacitor may be formed of (or including) the first electrode layer GAT1, the first portion GAT2_P1 of the second electrode layer GAT2, and the first portion ACT2_P1 of the second active layer ACT2, and the first portion ACT2_P1 of the second active layer ACT may be a semiconductor pattern doped with impurities. Other details have been described with reference to FIG. 1 to FIG. 17 so redundant descriptions will be omitted.

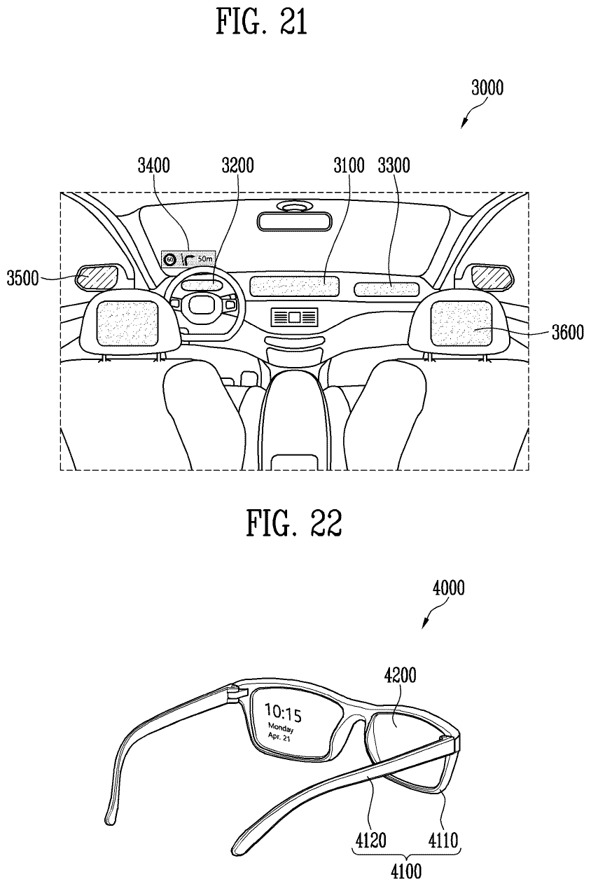

FIG. 19 schematically illustrates a block diagram of a display system according to an embodiment.

Referring to FIG. 19, a display system 1000 may include a processor 1100 and a display device 1200.

The processor 1100 may perform various tasks and calculations. In embodiments, the processor 1100 may include at least one of an application processor, a graphics processor, a microprocessor, a central processing unit (CPU), and the like. The processor 1100 may be electrically connected to the display device 1200 and other constituent elements of the display system 1000 through a bus system (or bus).

The processor 1100 may transmit image data IMG and a control signal CTRL to the display device 1200. The display device 1200 may display an image based on the image data IMG and the control signal CTRL. The display device 1200 may be configured similarly to the display device DD described with reference to at least FIG. 1. The image data IMG and the control signal CTRL may be provided as the input image data IMG and the control signal CTRL of FIG. 1, respectively.

The display system 1000 may include at least one of a computing system that provides image display functions, such as a smart watch, a mobile phone, a smart phone, a portable computer, a tablet personal computer (PC), a watch phone, an automotive display, a smart glass, a portable multimedia layer (PMP), a navigation system, and an ultra-mobile personal computer (UMPC). The display system 1000 may include at least one of a head-mounted display device (HMD), a virtual reality (VR) device, a mixed reality (MR) device, and an augmented reality (AR) device.

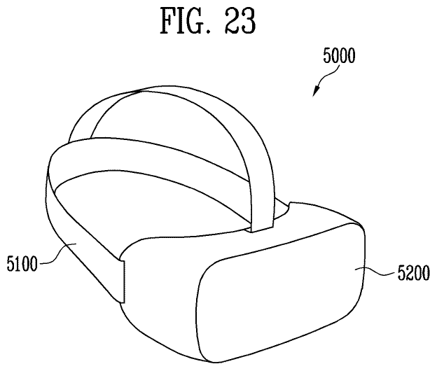

FIG. 20 to FIG. 23 schematically illustrate perspective views of application examples of the display system of FIG. 19 according to some embodiments.

Referring to FIG. 20, the display system 1000 of FIG. 19 may be applied to a smart watch 2000 including a display portion 2100 and a strap portion 2200.

The smart watch 2000 may be a wearable electronic device. For example, the smart watch 2000 may have a structure in which the strap portion 2200 is mounted on a user's wrist. The display system 1000 and/or the display device 1200 may be applied to the display portion 2100 so that image data including, for instance, time information may be provided to the user.

Referring to FIG. 21, the display system 1000 of FIG. 19 may be applied to an automotive display system 3000. The automotive display system 3000 may include a computing system that is provided inside and/or outside a vehicle to provide image data.

For example, the display system 1000 and/or the display device 1200 may be applied to at least one of an infotainment panel 3100, a cluster 3200, a co-driver (or passenger) display 3300, a heads-up display 3400, a side mirror display 3500, and a rear-seat display 3600, which are provided in, on, or part of the vehicle.

Referring to FIG. 22, the display system 1000 of FIG. 19 may be applied to smart glasses 4000. The smart glasses 4000 may be a wearable electronic device that may be worn on a user's head. For example, the smart glasses 4000 may be a wearable device for virtual reality, augmented reality, and/or mixed reality.

The smart glasses 4000 may include a frame 4100 and a lens portion 4200. The frame 4100 may include a housing 4110 supporting the lens portion 4200 and a leg portion 4120 for a user to wear. The leg portion 4120 may be physically connected to the housing 4110 through a hinge that can be folded or unfolded with respect to the housing 4110.

A battery, a touch pad, a microphone, and/or a camera may be embedded in (or otherwise supported via) one or more portions of the frame 4100. A projector that may output light and a processor that may control an optical signal and the like may be embedded in (or otherwise supported via) the frame 4100.

The lens portion 4200 may include an optical member configured to transmit light and/or reflect light. For example, the lens portion 4200 may include at least one of glass, a transparent synthetic resin, and the like.

The user's eyes may recognize visual information by the lens portion 4200 reflecting an image by an optical signal transmitted from the projector of the frame 4100 by a rear surface of the lens portion 4200 (for example, a surface facing the user's eye). For example, the user may recognize visual information, such as time and date information, displayed on or via the lens portion 4200. The projector and/or the lens portion 4200 may be a type of display device. The display device 1200 may be applied to (or as) the projector and/or the lens portion 4200.

Referring to FIG. 23, the display system 1000 of FIG. 19 may be applied to a head-mounted display device 5000.

The head-mounted display device 5000 may be a wearable electronic device that may be worn on a user's head. For example, the head-mounted display device 5000 may be a wearable device for virtual reality, mixed reality, and/or augmented reality.

The head-mounted display device 5000 may include a head-mounted band 5100 and a display device accommodation case 5200. The head-mounted band 5100 may be physically connected to the display device accommodation case 5200. The head-mounted band 5100 may include a horizontal band and/or a vertical band for fixing the head-mounted display device 5000 to the user's head. The horizontal band may be configured to at least partially surround the side portion of the user's head, and the vertical band may be configured to at least partially surround the upper portion of the user's head. However, embodiments are not limited to this example structure. For example, the head-mounted band 5100 may be implemented in the form of a spectacle frame, a helmet, and/or the like.

The display device accommodation case 5200 may accommodate the display system 1000 and/or the display device 1200.

Various embodiments may be applied to (or in association with) a display device and an electronic device including the same. For example, one or more embodiments may be applied to a digital television (TV), a three-dimensional (3D) TV, a mobile phone, a smart phone, a tablet computer, a VR device, a PC, a home electronic device, a laptop computer, a personal digital assistant (PDA), a personal media player (PMP), a digital camera, a music player, a portable game console, a navigation, a billboard, and/or the like.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a substrate including a display area and a non-display area;
a first active layer disposed on the substrate, a portion of the first active layer forming a channel area of a driving transistor of a sub-pixel circuit;
a first electrode layer disposed on the first active layer, a portion of the first electrode layer forming a control electrode of the driving transistor;
a second electrode layer including a first portion overlapping the first electrode layer in a direction perpendicular to the substrate; and
a second active layer including:
a first portion overlapping the first portion of the second electrode layer in the direction; and
a second portion forming a channel area of a switching transistor of the sub-pixel circuit.

2. The display device of claim 1, wherein
the sub-pixel circuit includes a capacitor electrically connected to the control electrode of the driving transistor, and
the capacitor includes electrodes formed by the portion of the first electrode layer, the first portion of the second electrode layer, and the first portion of the second active layer.

3. The display device of claim 1, wherein the first portion of the second active layer is a semiconductor pattern doped with impurities.

4. The display device of claim 1, wherein
the second electrode layer further includes a second portion, and
in the direction, the second portion of the second electrode layer is disposed between the second portion of the second active layer and the substrate.

5. The display device of claim 1, further comprising:
a third electrode layer disposed on the substrate, a portion of the third electrode layer forming a control electrode of the switching transistor,
wherein, in a view in the direction, the third electrode layer is spaced apart from the first portion of the second active layer.

6. The display device of claim 1, further comprising:
a light emitting element disposed on the display area and electrically connected to the sub-pixel circuit, the sub-pixel circuit including:
a first sub-pixel circuit configured to control a light emitting time of the light emitting element; and
a second sub-pixel circuit configured to provide a driving current to the light emitting element.

7. The display device of claim 6, wherein the first sub-pixel circuit includes:
a first transistor including a control electrode electrically connected to a first node, a first electrode electrically connected to a second node, and a second electrode electrically connected to a third node;
a first capacitor including a first electrode electrically connected to receive a sweep voltage and a second electrode electrically connected to the first node;
a second transistor including a control electrode electrically connected to receive a first write gate signal, a first electrode electrically connected to receive a data voltage, and a second electrode electrically connected to the second node;
a third transistor including a control electrode electrically connected to receive the first write gate signal, a first electrode electrically connected to the third node, and a second electrode electrically connected to the first node;
a fourth transistor including a control electrode electrically connected to receive an emission signal, a first electrode electrically connected to receive a (1-1)-th power voltage, and a second electrode electrically connected to the second node;
a fifth transistor including a control electrode electrically connected to receive the emission signal, a first electrode electrically connected to the third node, and a second electrode electrically connected to the second sub-pixel circuit; and
a sixth transistor including a control electrode electrically connected to receive a first initialization gate signal, a first electrode electrically connected to receive a first initialization voltage, and a second electrode electrically connected to the first node.

8. The display device of claim 7, wherein
the first transistor is an instance of the driving transistor, and
each of the second transistor, the third transistor, and the sixth transistor is a respective instance of the switching transistor.

9. The display device of claim 8, wherein electrodes of the first capacitor are formed by the portion of the first electrode layer, the first portion of the second electrode layer, and the first portion of the second active layer.

10. The display device of claim 6, wherein the second sub-pixel circuit includes:
a seventh transistor including a control electrode electrically connected to a fourth node electrically connected to the first sub-pixel circuit, a first electrode electrically connected to a fifth node, and a second electrode electrically connected to a sixth node;
a second capacitor including a first electrode electrically connected to receive a (1-2)-th power voltage and a second electrode electrically connected to the fourth node;
an eighth transistor including a control electrode electrically connected to receive a second write gate signal, a first electrode electrically connected to receive a data voltage, and a second electrode electrically connected to the fifth node;
a ninth transistor including a control electrode electrically connected to receive the second write gate signal, a first electrode electrically connected to the sixth node, and a second electrode electrically connected to the fourth node;
a tenth transistor including a control electrode electrically connected to receive an emission signal, a first electrode electrically connected to receive the (1-2)-th power voltage, and a second electrode electrically connected to the fifth node;
an eleventh transistor including a control electrode electrically connected to receive the emission signal, a first electrode electrically connected to the sixth node, and a second electrode electrically connected to the light emitting element;
a twelfth transistor including a control electrode electrically connected to receive a second initialization gate signal, a first electrode electrically connected to receive a first initialization voltage, and a second electrode electrically connected to the fourth node; and
a thirteenth transistor including a control electrode electrically connected to receive a bias gate signal, a first electrode electrically connected to receive a second initialization voltage, and a second electrode electrically connected to the light emitting element.

11. The display device of claim 10, wherein
the seventh transistor is an instance of the driving transistor, and
each of the eighth transistor, the ninth transistor, and the twelfth transistor is a respective instance of the switching transistor.

12. The display device of claim 11, wherein electrodes of the second capacitor are formed by the portion of first electrode layer, the first portion of the second electrode layer, and the first portion of the second active layer.

13. The display device of claim 1, further comprising:
a lower electrode layer disposed on the substrate,
wherein the lower electrode layer is disposed between the first active layer and the substrate in the direction.

14. The display device of claim 13, wherein at least a portion of the lower electrode layer is electrically connected to the first portion of the second electrode layer.

15. The display device of claim 14, wherein the at least the portion of the lower electrode layer and the first portion of the second electrode layer are electrically connected to one another in a region overlapping the non-display area in the direction.

16. A method of manufacturing a display device, the method comprising:
forming, on a substrate, a first active layer in a display area of the display device, a portion of the first active layer forming a channel area of a driving transistor of a sub-pixel circuit;
forming a first electrode layer on the first active layer, a portion of the first electrode layer forming a control electrode of the driving transistor;
forming, on the substrate, a second electrode layer including a first portion overlapping the first electrode layer in a direction perpendicular to the substrate; and
forming, on the substrate, a second active layer including:
a first portion overlapping the first portion of the second electrode layer in the direction; and
a second portion forming a channel area of a switching transistor of the sub-pixel circuit.

17. The method of claim 16, wherein
the sub-pixel circuit includes a capacitor electrically connected to the control electrode of the driving transistor, and
the capacitor includes electrodes formed by the portion of the first electrode layer, the first portion of the second electrode layer, and the first portion of the second active layer.

18. The method of claim 16, wherein the first portion of the second active layer is a semiconductor pattern doped with impurities.

19. The method of claim 16, further comprising:
forming a third electrode layer on the substrate, a portion of the third electrode forming a control electrode of the switching transistor,
wherein, in a view in the direction, the third electrode layer is spaced apart from the first portion of the second active layer.

20. The method of claim 16, further comprising:
forming a lower electrode layer on the substrate,
wherein at least a portion of the lower electrode layer is electrically connected to the first portion of the second electrode layer.
